(19) United States
(12) Patent Application Publication
(10) Pub. No.: US 2015/0208536 A1
(43) Pub. Date: Jul. 23, 2015

(54) WINDOW FOR DISPLAY DEVICE AND DISPLAY DEVICE INCLUDING THE SAME

(71) Applicant: SAMSUNG DISPLAY CO., LTD., Yongin-City (KR)

(72) Inventor: Jong Sung YOU, Asan-si (KR)

(21) Appl. No.: 14/487,214

(22) Filed: Sep. 16, 2014

(30) Foreign Application Priority Data
Jan. 22, 2014 (KR) 10-2014-0007861

(51) Int. Cl. H05K 5/03; B32B 27/38; B32B 27/08; B32B 7/12; B32B 17/10

(52) U.S. Cl. CPC H05K 5/03; B32B 7/12; B32B 17/10779; B32B 27/08; B32B 27/38; B32B 2457/206; B32B 2457/202

(57) ABSTRACT

A window for a display device may include a base member, a printing layer and an adhesive film. The base member may have a planar shape corresponding to a display area and a peripheral area adjacent to the display area. The printing layer may be on the base member and may correspond to the peripheral area. The adhesive film may be on the printing layer and may cover a boundary between the printing layer and the base member.

### CROSS-REFERENCE TO RELATED APPLICATION

The present application claims priority under 35 U.S.C. §119 to Korean Patent Application No. 10-2014-0007861, filed on Jan. 22, 2014, in the Korean Intellectual Property Office, and entitled: “Window For Display Device And Display Device Comprising The Same,” which is incorporated by reference herein in its entirety.

### BACKGROUND

1. Field

Embodiments relate to a window for a display device and a display device including the same.

2. Description of the Related Art

Recently, various mobile electronic devices such as mobile phones, navigations, digital cameras, e-books, portable game consoles, or various devices, to which a liquid crystal display (LCD) or an organic light emitting diode (OLED) display is applied as a display device, have been used. A general display device used for the mobile devices may include a window that is transparently configured so that a user can view a display area in the front of a display panel. The window ideally has strength against external impact so as to protect a display panel and the like in the device due to a configuration on the out most side of the device. In the window, a black printing layer may be at a part of the inside of the window corresponding to a non-display area of the display panel to prevent the inside of the display device from being seen.

### SUMMARY

Embodiments are directed to a window for a display device may include a base member, a printing layer and an adhesive film. The base member may have a planar shape corresponding to a display area and a peripheral area adjacent to the display area. The printing layer may be on the base member and may correspond to the peripheral area. The adhesive film may be on the printing layer and may cover a boundary between the printing layer and the base member.

The base member may include a polymer resin layer or glass layer, an adhesive layer on the polymer resin layer or the glass layer, and a PET film on the adhesive layer. The printing layer may include a first printing layer on the base member, a second printing layer on the first printing layer, a third printing layer on the second printing layer, a fourth printing layer on the third printing layer. Cross sections of the first printing layer, the second printing layer, the third printing layer and the fourth printing layer may have a stepped shape.

The adhesive film may be a thermosetting film. The adhesive film may include at least one of an epoxy-based compound and a urethane-based compound. The adhesive film may include the epoxy-based compound, and at least one of a bisphenol curing agent and an imidazole curing agent. The adhesive film may include the urethane-based compound, and at least one of isocyanate and polyol. The adhesive film may be a photo-curable film. The photo-curable film may include a photoinitiator. The photo-curable film may include at least one of a monomer and an oligomer, and the oligomer includes at least one of a urethane-based oligomer, an acryl-based oligomer, and a silicon-based oligomer. The thickness of the adhesive film is from about 5 μm to about 50 μm. The glass transition temperature (Tg) of the adhesive film may be from about 90° C. to about 120° C. A pattern portion may be on the base member.

A display panel may include a display area displaying an image and a peripheral area, and a window on the display panel. The window may include a base member, a printing layer corresponding to the peripheral area and on one side of the base member, and an adhesive film covering a boundary between the printing layer and the base member. The adhesive film may be a thermosetting film. The adhesive film may include at least one of an epoxy-based compound and a urethane-based compound. An epoxy-based compound-containing adhesive film may include at least one of a bisphenol curing agent and an imidazole curing agent. A urethane-based compound-containing adhesive film may include at least one of isocyanate and polyol. The adhesive film may be a photo-curable film. The photo-curable film may include at least one of a photoinitiator, a monomer, and an oligomer. The oligomer may include at least one of a urethane-based oligomer, an acryl-based oligomer, and a silicon-based oligomer. A thickness of the adhesive film may be from about 5 μm to about 50 μm. A glass transition temperature (Tg) of the adhesive film may be from about 90° C. to about 120° C.

### BRIEF DESCRIPTION OF THE DRAWINGS

Features will become apparent to those of ordinary skill in the art by describing in detail exemplary embodiments with reference to the attached drawings in which:

FIG. 1 illustrates an exploded perspective view of a display device.

FIG. 2 illustrates a plan view of a window for the display device.

FIG. 3 illustrates a cross-sectional view taken along line of FIG. 2 according to an embodiment.

FIG. 4 illustrates a cross-sectional view taken along line of FIG. 2 according to an embodiment.

FIGS. 5A and 5B illustrate window images for an Example and a Comparative Example, respectively.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. As those skilled in the art would realize, the described embodiments may be modified in various different ways, all without departing from the spirit or scope of the present disclosure. In the drawings, the thickness of layers, films, panels, regions, and the like, may be exaggerated for clarity. Like reference numerals designate like elements throughout the specification. When an element such as a layer, film, region, or substrate is referred to as being “on” another element, it can be directly on the other element or intervening elements may also be present. When an element is referred to as being “directly on” another element, there are no intervening elements present.

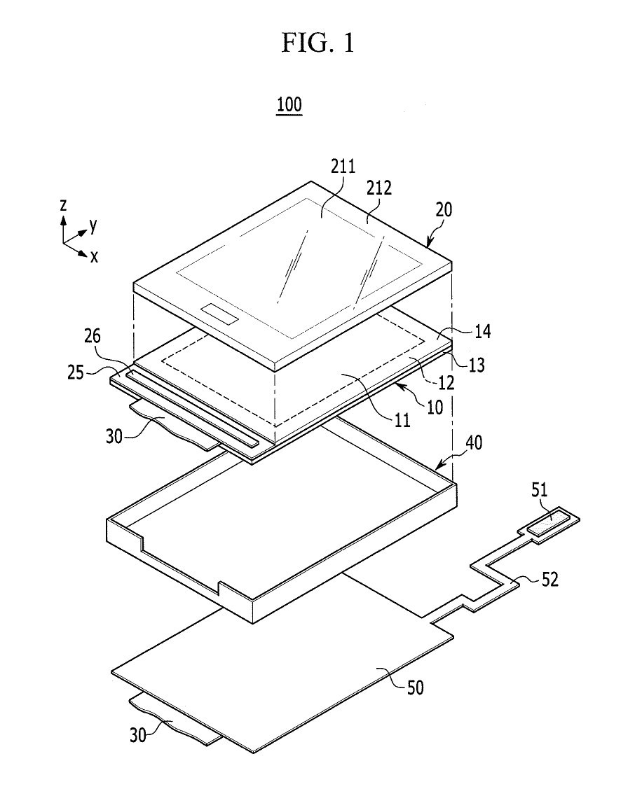

FIG. 1 illustrates an exploded perspective view of a display device including a window. Referring to FIG. 1, a display device 100 may include a display panel 10 displaying an image, a housing 40 receiving the display panel 10 and various components, and a window 20 in front of the display panel 10 to protect the display panel 10. The display panel 10 may be, for example, an organic light emitting panel. The display panel 10 may alternatively or additionally include one or more other display panels other than the organic light emitting panel, for example, various display panels, for example, a liquid crystal display panel, a plasma display panel, an electrophoretic display panel, an electrowetting display panel, and so forth. A flat or curved display panel, for example, may be employed.

Pixels that are basic units of image expression may be arranged in a matrix on a first substrate 13 of the display panel 10, and a second substrate 14 may adhere to the first substrate 13 through a sealing member to protect the pixels. The first substrate 13 may be a rear substrate and the second substrate 14 may be a front substrate. For example, in an active matrix type organic light emitting panel, the pixel may include an organic light emitting element configured by an anode, an organic light emitting layer, and a cathode, and a driving circuit unit driving the organic light emitting element. The driving circuit unit may include a thin film transistor. A data line may be connected to a source terminal of the thin film transistor, and a gate line may be connected to a gate terminal. In addition, any one of the anode and the cathode of the organic light emitting element may be connected to a drain terminal.

The data line and the gate line may be connected to a printed circuit board 50 through a flexible printed circuit 30. When an electric signal is input to the source terminal and the gate terminal of the thin film transistor through the printed circuit board 50, for example, the thin film transistor may be turned on or off according to the signal input to output an electric signal for the pixel driving to the drain terminal.

An IC chip 26 may be mounted on the first substrate 13 to control the display panel 10. The IC chip 26 may generate timing signals for applying a data driving signal and a gate driving signal at a proper timing. In addition, the signals may be applied to the data line and the gate line of the display panel 10, respectively. A passivation layer 25 may be around the IC chip 26 to protect the IC chip 26. Electronic elements for processing the driving signal may be mounted on the printed circuit board 50. The printed circuit board 50 may include a connector 51 and an extension 52, and the extension 52 may be installed at one end of the connector 51 to transfer an external signal to the printed circuit board 50.

The window 20 for protecting the display panel 10 may be in front of the display panel 10. The window 20 may serve to protect the display panel 10 so as not to be broken by external impact. In addition, the window 20 may be attached to the display panel 10 by a predetermined adhesive layer. Alternatively, the display panel 10 and the window 20 may be spaced apart from each other with an air layer therebetween. In order to bond the display panel 10 and the window 20, a liquid resin or a tape (for example, WB-tape) that is an adhesive member may be used.

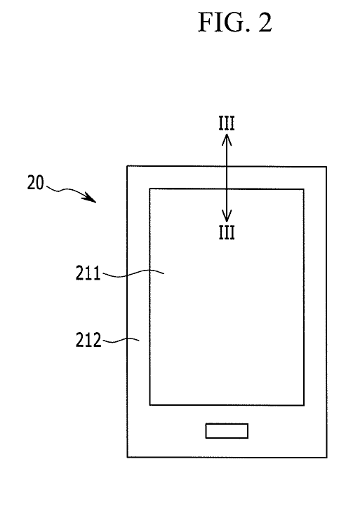

The window 20 may include a transparent portion 211 that may be at a portion corresponding to the display area 11 of the display panel 10 so that the display area 11 may be viewed externally, and an opaque portion 212 that may be at an area corresponding to a peripheral area 12 of the display panel 10 in order to prevent the peripheral area 12 from being viewed externally. The opaque portion 212 may serve to cover a wiring, a component, or the like in the peripheral area 12 of the display panel 10 so as not to be viewed outside. In the opaque portion 212, there may be a printing layer having a logo or a pattern of a product or having a predetermined color (for example, black, white, or the like). The window 20 is described in further detail with reference to FIGS. 2 to 4.

The housing 40 may be mounted on the display panel 10. In FIG. 1, the housing configured as one member is illustrated as an example. However, the housing 40 may be configured by coupling two or more members. The housing configured as one member is described herein as an example. The display device may further include a contact sensing panel. The contact sensing panel may use a resistive touch panel, a capacitive touch panel, or the like.

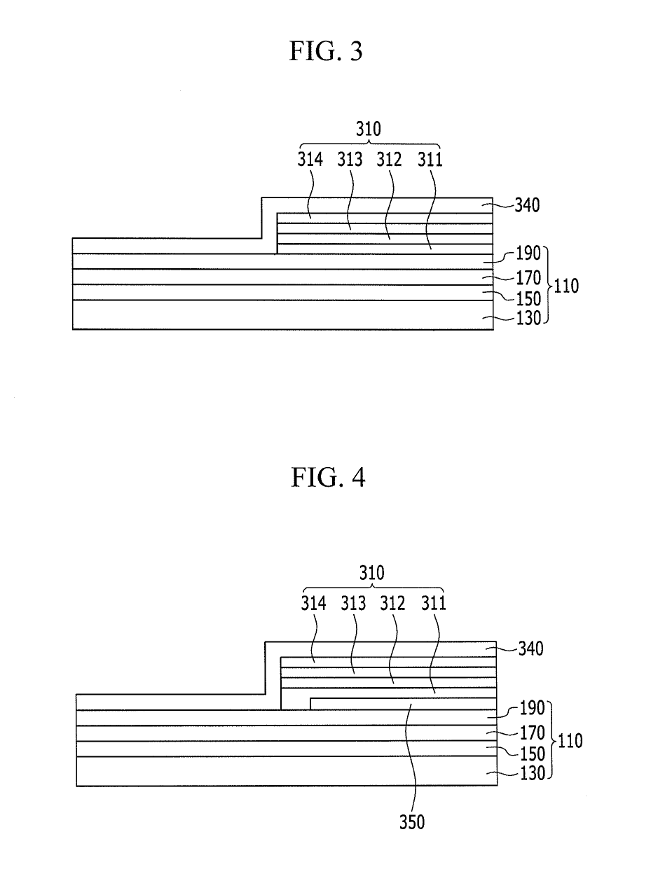

A window for a display device is described with reference to FIGS. 2 and 3. FIG. 2 illustrates a plan view of a window for the display device illustrated in FIG. 1, and FIG. 3 illustrates a cross-sectional view taken along line III-III of FIG. 2. The window for the display device may include a base member including a polymer resin layer or a glass layer 130, an adhesive layer 150, and a PET film 170, and a printing layer 310 on the base member 110, and an adhesive film. The window 20 may have flexibility when, for example, the base member 110 includes the polymer resin layer, and as an example, may be a film type.

The base member 110, as illustrated in FIG. 2, may include a transparent portion 211 that may be at a portion corresponding to the display area 11 of the display panel 10 so that the display area 11 may be recognized from the outside, and an opaque portion 212 that may be at an area corresponding to a peripheral area 12 of the display panel 10 in order to prevent the peripheral area 12 from being recognized from the outside. The opaque portion 212 serves to cover a wiring, a component, or the like in the peripheral area 12 of the display panel 10 so as not to be viewed outside.

As illustrated in FIG. 2, the transparent portion 211 may be, for example, surrounded by the opaque portion 212, or, for example, may be divided into two regions with the transparent portion 211 therebetween on a plane. The polymer resin layer or glass layer 130 may substantially determine a shape of the window 20 for the display device, and may have a planar shape corresponding to the display area and the peripheral area of the display panel. The polymer resin layer or glass layer 130 may have, for example, a planar shape, or may have a curved shape or other shapes. A material of the polymer resin layer or glass layer 130 may include, for example, polyethyleneterephthalate (PET), triacetyl cellulose (TAC), polyimide (PI), polycarbonate (PC), temperature polyurethane (TPU), silicon rubber, or the like. Any suitable material that may be applied to the display device to ensure transparency after curing may be used.

The adhesive layer 150 may be between the polymer resin layer or glass layer 130 and the film 170, and may be a transparent material that bonds the polymer resin layer or glass layer 130 and the film 170 to each other. The PET film 170 may be on the adhesive layer 150, and as an example, may improve hardness of the window 20 for the display device. For improving the hardness, for example, a high-hardness film 170 may be used. Any suitable film that may improve a property for the window may be used.

When the PET film 170 is coupled with the polymer resin layer or glass layer 130 through the adhesive layer 150 described herein, for example, a roll laminating process may be used. The PET film 170 may be on an outer surface of the polymer resin layer 130 and pressurized and attached by a roller. In order to perform the roll laminating process, the adhesive layer 150 described herein may be between the PET film 170 and the polymer resin layer or glass layer 130. A UV molding layer 190 may be on the PET film 170, or may be omitted. The UV molding layer 190 may have adhesion through a UV curing process.

The printing layer 310 may include a first printing layer 311, a second printing layer 312, a third printing layer 313, and a fourth printing layer 314 that may include respective openings. The printing layer 310 may be divided, for example, into four layers. Any suitable number of layers may be used, for example, a single layer or any number of multi-layers. The first printing layer 311, the second printing layer 312, the third printing layer 313, and the fourth printing layer 314 may include openings, respectively.

The first printing layer 311, the second printing layer 312, the third printing layer 313, and the fourth printing layer 314 may correspond to the opaque portion 212, and the openings included in the first printing layer 311, the second printing layer 312, the third printing layer 313, and the fourth printing layer 314 may correspond to the transparent portion 211. The opening may be, for example, a quadrangle on the plane. Any suitable shape that allows transmission of light may be used.

Planar areas of the first printing layer 311, the second printing layer 312, the third printing layer 313, and the fourth printing layer 314 may be the same as or different from each other, and for example, may have a stepped cross section as illustrated in FIG. 3. That is, the planar areas may be decreased toward the fourth printing layer 314 from the first printing layer 311.

The first printing layer 311 may be on one side of the base member 110 including the polymer resin layer or glass layer 130, the adhesive layer 150, the PET film 170, and the like, corresponding to a part of the opaque portion 212 of the base member 110. FIG. 3 shows the first printing layer 311 corresponding, for example, the entire portion of the opaque portion 212. The first printing layer 311 need not correspond to the entire portion of the opaque portion 212 and may correspond to lesser or greater portions as appropriate. The first printing layer 311 may absorb or reflect light that may be incident from the other side of the base member 110. The first printing layer 311 may be white, for example, as white may reflect the largest degree of the light for an opaque material. Any suitable color or combination of colors may be used. For example, the first printing layer 311 may have any color such as black, pink, and/or navy, which absorbs all or some portion of light incident thereon. The first printing layer 311 may be provided as a plurality of layers. For example, the first printing layer 311 having white may be provided with more layers than the first printing layer having other colors as white blocks less external light compared with other colors.

The second printing layer 312 may be on the base member 110 and the first printing layer 311, and may correspond to at least a part of the first printing layer 311. As illustrated in FIG. 3, the second printing layer may have a smaller planar area than the first printing layer 311. Accordingly, the cross sections of the first printing layer 311 and the second printing layer 312 may have a stepped shape.

The second printing layer 312 absorbs and/or reflects the light input from the other side of the base member 110 together with the first printing layer 311. Because the second printing layer 312 may be recognized outside the display device 100 by light input from the other side of the base member 110 to pass through the first printing layer 311, the second printing layer 312 may have any color that may maintain the color of the first printing layer 311.

The second printing layer 312 may be provided as a plurality of layers, and may include an opening corresponding to the opening of the first printing layer 311. The opening included in the second printing layer 312 may be, for example, a quadrangle corresponding to the opening included in the first printing layer 311 on the plane. Any suitable shape that transmits light may be used.

The first printing layer 311 and the second printing layer 312 may be the same material or a material having the same characteristic. The first printing layer 311 and the second printing layer 312 may be divided, for example, as separate layers, or may constitute a single layer or any suitable number of layers.

The third printing layer 313 and the fourth printing layer 314 may be on the second printing layer 312, and prevent or reduce the light input toward the opening from being reflected by at least one of the first and second printing layers 311 and 312. The third printing layer 313 and the fourth printing layer 314 may be, for example, black. The third printing layer 313 and the fourth printing layer 314 may have any color that prevents or reduces the light from being reflected by at least one of the first and second printing layers 311 and 312.

At least one of the third printing layer 313 and the fourth printing layer 314 may be provided as a plurality of layers like the first printing layer 311 or the second printing layer 312. The third printing layer 313 and the fourth printing layer 314 may be the same material or a material having the same characteristic. The third printing layer 313 and the fourth printing layer 314 may be divided, for example, as separate layers, or may constitute a single layer or any suitable number of layers.

The adhesive film 340 may be on a plurality of printing layers 310. The adhesive film 340 may be at a covering a boundary between the printing layer 310 at the opaque portion 212 and the base member 110. This configuration may prevent the printing layer from being released or discolored by a liquid resin and the like that may be used in a process of coupling the window 20 and the display panel 10. The adhesive film 340 may be attached as a film form, for example, and/or may be a layer formed by coating and curing an adhesive of a material described herein or otherwise suitable.

The adhesive film 340, for example, may be a thermosetting film. The adhesive film 340 may include at least one of epoxy-based and urethane-based compounds. When the adhesive film 340 includes the epoxy-based compound, for example, the adhesive film 340 may include at least one of bisphenol and imidazole curing agents. The adhesive film 340 may include, for example, bisphenol F and imidizole curing agents, or may include bisphenol A and imidazole curing agents. When the adhesive film 340 includes, for example, the urethane-based compound, the adhesive film 340 may include at least one of isocyanate and polyol.

The adhesive film 340 may be, for example, a photo-curable film. The adhesive film 340 that is the photo-curable film may include a photoinitiator.

The adhesive film 340 may include at least one of a monomer and an oligomer in addition to the photoinitiator. When the adhesive film 340 includes the oligomer, the oligomer may include, for example, at least one of urethane-based, acryl-based, and silicon-based oligomers. A glass transition temperature (Tg) of the adhesive film 340 having the material described herein may be, for example, from about 90° C. to about 120° C. Further, the adhesive film 340 having the material described herein may have, for example, a thickness of from about 5 μm to about 50 μm. Even when the window 20 including the aforementioned adhesive film 340 is bonded to the display panel 10, for example, it may be possible to prevent the printing layer from being discolored or released by the adhesive resin.

A window for a display device is described with reference to FIGS. 2 and 4 accordingly to an embodiment. FIG. 4 illustrates cross-sectional view of a window. A window 20 for a display device may include a base member 110 including a polymer resin layer or a glass layer 130, an adhesive layer 150, and a PET film 170, and a printing layer 310 on the base member 110, and a printing layer 310 and an adhesive film 340 on the base member 110.

The base member 110, as illustrated in FIG. 2, may include a transparent portion 211 that may be at a portion corresponding to the display area 11 of the display panel 10 so that the display area 11 may be recognized outside, and an opaque portion 212 that may be at an area corresponding to a peripheral area 12 of the display panel 10 in order to prevent the peripheral area 12 from being recognized from the outside. The opaque portion 212 may serve to cover a wiring, a component, or the like in the peripheral area 12 of the display panel 10 so as not to be viewed outside.

The polymer resin layer or glass layer 130 may substantially determine a shape of the window 20 for the display device, and has a planar shape corresponding to the display area and the peripheral area of the display panel. The polymer resin layer or glass layer 130 may have a planar shape, for example, or may have a curved shape or other shapes. A material of the polymer resin layer or glass layer 130 may include, for example, polyethyleneterephthalate (PET), triacetyl cellulose (TAC), polyimide (PI), polycarbonate (PC), temperature polyurethane (TPU), silicon rubber, or the like. Any suitable material may be applied to the display device to ensure transparency after curing.

The adhesive layer 150 may be between the polymer resin layer or glass layer 130 and the film 170, and may be a transparent material that bonds the polymer resin layer or glass layer 130 and the film 170 to each other. The PET film 170 may be on the adhesive layer 150, and as an example, may improve hardness of the window 20 for the display device described herein. To improve hardness, a high-hardness film 170, for example, may be adopted. Any suitable film that may improve a property of the window may be used.

When the PET film 170 is coupled with the polymer resin layer or glass layer 130 through the adhesive layer 150 described herein, for example, a roll laminating process may be used. The PET film 170 may be on an outer surface of the polymer resin layer 130 and pressurized and attached by a roller. In order to perform the roll laminating process, the adhesive layer 150 described herein may be between the PET film 170 and the polymer resin layer or glass layer 130.

The printing layer 310 may include a first printing layer 311, a second printing layer 312, a third printing layer 313, and a fourth printing layer 314 that include respective openings. The first printing layer 311, the second printing layer 312, the third printing layer 313, and the fourth printing layer 314 may include openings, respectively. The first printing layer 311, the second printing layer 312, the third printing layer 313, and the fourth printing layer 314 may correspond to the opaque portion 212, and the openings included in the first printing layer 311, the second printing layer 312, the third printing layer 313, and the fourth printing layer 314 may correspond to the transparent portion 211. The opening may be, for example, a quadrangle on the plane. Any suitable shape that transmits light may be used for the opening. Planar areas of the first printing layer 311, the second printing layer 312, the third printing layer 313, and the fourth printing layer 314 may be the same as or different from each other, and for example, may have a stepped cross section as illustrated in FIG. 3. That is, the planar areas may be decreased toward the fourth printing layer 314 from the first printing layer 311.

The first printing layer 311 may be on one side of the base member 110 including the polymer resin layer or glass layer 130, the adhesive layer 150, the PET film 170, and the like, corresponding to a part of the opaque portion 212 of the base member 110. FIG. 3 shows the first printing layer 311 corresponding, for example, to the entire portion of the opaque portion 212. The first printing layer 311 need not correspond to the entire portion, and may correspond to lesser or greater portions thereof. The first printing layer 311 absorbs or reflects light that may be incident from the other side of the base member 110. The first printing layer 311 may be white, for example, as white may reflect the largest degree of light for an opaque material. The first printing layer 311 may be any suitable color. For example, the first printing layer 311 may be black, pink, and/or navy, which absorbs all or part of light incident thereon. The first printing layer 311 may be provided as a plurality of layers. For example, the first printing layer 311 may be white and may be provided as more layers than the first printing layer having other colors, as white blocks less external light compared with other colors.

The second printing layer 312 may be on the base member 110 and the first printing layer 311, and may correspond to at least a part of the first printing layer 311. As illustrated in FIG. 3, the second printing layer may have a smaller planar area than the first printing layer 311. Accordingly, the cross sections of the first printing layer 311 and the second printing layer 312 may have a stepped shape. The second printing layer 312 may absorb or reflect the light input from the other side of the base member 110 together with the first printing layer 311. Because the second printing layer 312 may be recognized outside the display device 100 by light input from the other side of the base member 110 to pass through the first printing layer 311, the second printing layer 312 may have any color that may maintain the color of the first printing layer 311.

The second printing layer 312 may be provided as a plurality of layers, and may include an opening corresponding to the opening of the first printing layer 311. The opening included in the second printing layer 312 may be, for example, a quadrangle corresponding to the opening included in the first printing layer 311 on the plane. The first printing layer 311 may be any suitable shape that transmits light.

The third printing layer 313 and the fourth printing layer 314 may be on the second printing layer 312, and prevents or reduces the light input toward the opening from being reflected by at least one of the first and second printing layers 311 and 312. The third printing layer 313 and the fourth printing layer 314 may be, for example, black. The third printing layer 313 and the fourth printing layer 314 may be any suitable color that prevents or reduces the light from being reflected by at least one of the first and second printing layers 311 and 312. At least one of the third printing layer 313 and the fourth printing layer 314 may be provided as a plurality of layers like the first printing layer 311 or the second printing layer 312. The third printing layer 313 and the fourth printing layer 314 may be the same material or a material having the same characteristic. The third printing layer 313 and the fourth printing layer 314 may be divided, for example, as separate layers, or may be represented as one layer or any suitable number of layers.

A pattern portion 350 may be on the printing layer 310. The pattern portion 350, as an area that a user may recognize a predetermined pattern at the opaque portion 212, may include, for example, a hair line such as minute protrusions and/or depressions. The hair line means fine pattern expanding one direction.

The adhesive film 340 may be on the pattern portion 350. The adhesive film 340 may cover a boundary between the printing layer 310 at the opaque portion 212 and the base member 110. This configuration may prevent the printing layer from being released or discolored by penetrating a liquid resin and the like, which may be used in a process of coupling the window 20 and the display panel 10, into the printing layer during the curing process. The adhesive film 340 may be, for example, a thermosetting film.

The adhesive film 340 may include at least one of epoxy-based and urethane-based compounds. When the adhesive film 340 includes the epoxy-based compound, for example, the adhesive film 340 may include at least one of bisphenol and imidazole curing agents. The adhesive film 340 may include, for example, bisphenol F and imidizole curing agents, or include bisphenol A and imidazole curing agents. When the adhesive film 340 includes a urethane-based compound, the adhesive film 340 may include, for example, at least one of isocyanate and polyol. The adhesive film 340 may include any suitable composition. The adhesive film 340 may be, for example, a photo-curable film. The adhesive film 340 that is a photo-curable film may include a photoinitiator. The adhesive film 340 may include, for example, at least one of a monomer and an oligomer in addition to the photoinitiator. When the adhesive film 340 includes the oligomer, the oligomer may include, for example, at least one of urethane-based, acryl-based, and silicon-based oligomers. A glass transition temperature (Tg) of the adhesive film 340 having the material described herein may be, for example, from about 90° C. to about 120° C. The adhesive film 340 having the material described herein may have a thickness, for example, of from about 5 μm to about 50 μm.

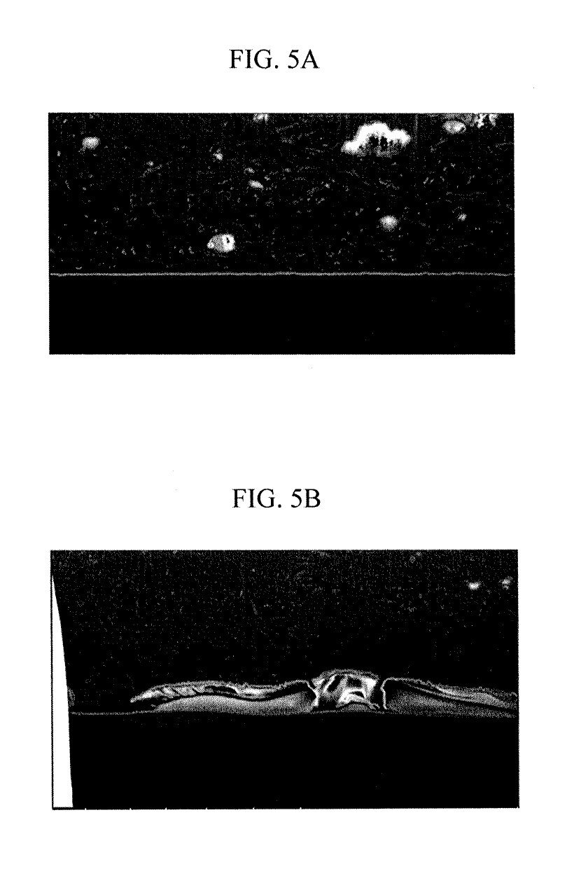

Even when the window 20 including the aforementioned adhesive film 340 is bonded to the display panel 10, for example, it may be possible to prevent the printing layer from being discolored or released by the resin. A window according to an Example and a window according to a Comparative Example are described with reference to FIGS. 5A and 5B.

First, like FIG. 5A, it can be seen that in the window according to the Example, a boundary between an opaque portion and a transparent portion, that is, a boundary between a printing layer and a base member is normal and has no particular defect. However, like FIG. 5B, in the window according to the Comparative Example, it can be seen that releasing of the printing layer on the window occurs due to a liquid resin used during the curing process for coupling of the display panel and the window.

Further, with respect to the window with the adhesive film according to an Example and the Comparative Example, existence of releasing or discoloration was observed through a sample test.

TABLE 1

| | | Comparative |
|---|---|---|
| Classification | Example | Example |
| Existence of releasing with | 0 | 28 |
| respect to 30 samples (number) | | |

As described in Table 1, in the window with the adhesive film according to the Example, releasing or discoloration did not occur in all of the 30 samples. However, in the window according to the Comparative Example without the adhesive film, it was seen that releasing or discoloration occurred in 28 samples among the 30 samples. That is, it can be seen that in the window including the adhesive film according to the Example, discoloration and releasing occurring between the printing layer and the base member may be significantly reduced.

By way of summation and review, a display device has been developed, in which the printing layer has colors (for example, navy, white, pink, or the like) other than black, or has a predetermined pattern. The window for a display device as described herein may prevent discoloration or releasing occurring in the printing layer and reduce a defect and the like occurring during mass production.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A window for a display device, comprising:
a base member having a planar shape corresponding to a display area and a peripheral area adjacent to the display area;
a printing layer on the base member corresponding to the peripheral area; and
an adhesive film on the printing layer and covering a boundary between the printing layer and the base member.

2. The window for the display device as claimed in claim 1, wherein the base member includes a polymer resin layer or glass layer, an adhesive layer on the polymer resin layer or the glass layer, and a PET film on the adhesive layer.

3. The window for the display device as claimed in claim 1, wherein the printing layer includes:
a first printing layer on the base member;
a second printing layer on the first printing layer;
a third printing layer on the second printing layer; and
a fourth printing layer on the third printing layer; and
cross sections of the first printing layer, the second printing layer, the third printing layer, and the fourth printing layer have a stepped shape.

4. The window for the display device as claimed in claim 1, wherein the adhesive film is a thermosetting film.

5. The window for the display device as claimed in claim 4, wherein the adhesive film includes at least one of an epoxy-based compound and a urethane-based compound.

6. The window for the display device as claimed in claim 5, wherein the adhesive film includes the epoxy-based compound, and at least one of a bisphenol curing agent and an imidazole curing agent.

7. The window for the display device as claimed in claim 5, wherein the adhesive film includes the urethane-based compound, and at least one of isocyanate and polyol.

8. The window for the display device as claimed in claim 1, wherein the adhesive film is a photo-curable film.

9. The window for the display device as claimed in claim 8, wherein the photo-curable film includes a photoinitiator.

10. The window for the display device as claimed in claim 9, wherein the photo-curable film includes at least one of a monomer and an oligomer, and the oligomer includes at least one of a urethane-based oligomer, an acryl-based oligomer, and a silicon-based oligomer.

11. The window for the display device as claimed in claim 1, wherein a thickness of the adhesive film is from about 5 μm to about 50 μm.

12. The window for the display device as claimed in claim 1, wherein a glass transition temperature (T_{g}) of the adhesive film is from about 90° C. to 120° C.

13. The window for the display device as claimed in claim 1, further comprising a pattern portion on the base member.

14. A display device, comprising:
a display panel including a display area displaying an image and a peripheral area; and
a window on the display panel, the window including a base member, a printing layer corresponding to the peripheral area and on one side of the base member, and an adhesive film covering a boundary between the printing layer and the base member.

15. The display device as claimed in claim 14, wherein the adhesive film is a thermosetting film.

16. The display device as claimed in claim 15, wherein the adhesive film includes at least one of an epoxy-based compound and a urethane-based compound, an epoxy-based compound-containing adhesive film including at least one of a bisphenol curing agent and an imidazole curing agent, and a urethane-based compound-containing adhesive film includes at least one of isocyanate and polyol.

17. The display device as claimed in claim 14, wherein the adhesive film is a photo-curable film.

18. The display device as claimed in claim 17, wherein the photo-curable film includes at least one of a photoinitiator, a monomer, and an oligomer, and the oligomer includes at least one of a urethane-based oligomer, an acryl-based oligomer, and a silicon-based oligomer.

19. The display device as claimed in claim 14, wherein a thickness of the adhesive film is from about 5 μm to about 50 μm.

20. The display device as claimed in claim 14, wherein a glass transition temperature (T_{g}) of the adhesive film is from about 90° C. to about 120° C.
